(19) United States
(12) Patent Application Publication
(10) Pub. No.: US 2022/0114610 A1
(43) Pub. Date: Apr. 14, 2022

(54) MOBILE OBJECT MANAGEMENT DEVICE, MOBILE OBJECT MANAGEMENT SYSTEM, MOBILE OBJECT MANAGEMENT METHOD, AND TERMINAL DEVICE

(71) Applicant: Toyota Jidosha Kabushiki Kaisha, Toyota-shi Aichi-ken (JP)

(72) Inventor: Ai Miyata, Okazaki-shi (JP)

(73) Assignee: Toyota Jidosha Kabushiki Kaisha, Toyota-shi Aichi-ken (JP)

(21) Appl. No.: 17/371,596

(22) Filed: Jul. 9, 2021

(30) Foreign Application Priority Data
Oct. 8, 2020 (JP) 2020-170805

(51) Int. Cl. G06Q 30/02; B60L 58/12; B60L 53/62; G06Q 50/30; G06Q 10/06; G05B 19/042

(52) U.S. Cl. CPC G06Q 30/0222; B60L 58/12; B60L 53/62; G06Q 50/30; G01R 31/382; G06Q 30/0215; G06Q 30/0226; G05B 19/042; G06Q 10/06315

(57) ABSTRACT

A mobile object management device includes a control unit configured to calculate an incentive which is provided to a user when the user moves a motor-driven mobile object that is driven by a battery to a charging station configured to charge the motor-driven mobile object based on a state of charge of the battery. The control unit is configured to output information on the motor-driven mobile object and information on the incentive to a terminal device in correlation.

### CROSS-REFERENCE TO RELATED APPLICATION

This application claims priority to Japanese Patent Application No. 2020-170805 filed on Oct. 8, 2020, incorporated herein by reference in its entirety.

### BACKGROUND

### 1. Technical Field

The present disclosure relates to a mobile object management device, a mobile object management system, a mobile object management method, and a terminal device.

### 2. Description of Related Art

In the related art, a user participation type rental cycle operation system is known. For example, Japanese Unexamined Patent Application Publication No. 2019-148928 (JP 2019-148928 A) discloses a system that provides an incentive for movement of a vehicle between ports by a user.

### SUMMARY

A motor-driven mobile object such as a motor-driven vehicle needs to be managed in consideration of a state of charge of a battery therein. There is demand for a decrease in a management burden of a motor-driven mobile object.

The present disclosure is provided to decrease a management burden of a motor-driven mobile object.

According to an aspect of the present disclosure, there is provided a mobile object management device including a control unit configured to calculate an incentive which is provided to a user when the user moves a motor-driven mobile object that is driven by a battery to a charging station configured to charge the motor-driven mobile object based on a state of charge of the battery. The control unit is configured to output information on the motor-driven mobile object and information on the incentive to a terminal device in correlation.

A mobile object management system according to another aspect of the present disclosure includes the mobile object management device and the terminal device.

According to another aspect of the present disclosure, there is provided a mobile object management method including: calculating an incentive which is provided to a user when the user moves a motor-driven mobile object that is driven by a battery to a charging station configured to charge the motor-driven mobile object based on a state of charge of the battery; and outputting information on the motor-driven mobile object and information on the incentive to a terminal device in correlation.

According to an aspect of the present disclosure, there is provided a terminal device including: an output unit configured to output information on a motor-driven mobile object that is driven by a battery and information on a station of the motor-driven mobile object; an input unit configured to receive an input for selecting the motor-driven mobile object which is rented to a user and an input for selecting a return station to which the motor-driven mobile object is returned by the user; and a control unit configured to output information for selecting the motor-driven mobile object and the return station to a mobile object management device. The control unit is configured to acquire information on an incentive which is determined based on a state of charge of the battery and which is provided to the user from the mobile object management device and to cause the output unit to output the information on the motor-driven mobile object and the information on the incentive in correlation.

With the mobile object management device, the mobile object management system, the mobile object management method, and the terminal device according to the aspects of the present disclosure, it is possible to decrease a management burden of a motor-driven mobile object.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a block diagram illustrating an example of a configuration of a mobile object management system according to an embodiment;

FIG. 2 is a diagram illustrating a display example of a map in which a low-SOC station is distinguishable;

FIG. 3 is a diagram illustrating a display example of a map in which a charging station is distinguishable;

FIG. 4 is a flowchart illustrating an example of a routine of a mobile object management method according to an embodiment;

FIG. 5 is a flowchart illustrating an example of a routine of a terminal control method according to an embodiment;

FIG. 6 is a flowchart illustrating an example of a routine of first selecting a departure station; and

FIG. 7 is a flowchart illustrating an example of a routine of first selecting an arrival station.

### DETAILED DESCRIPTION OF EMBODIMENTS

Configuration example of mobile object management system 1

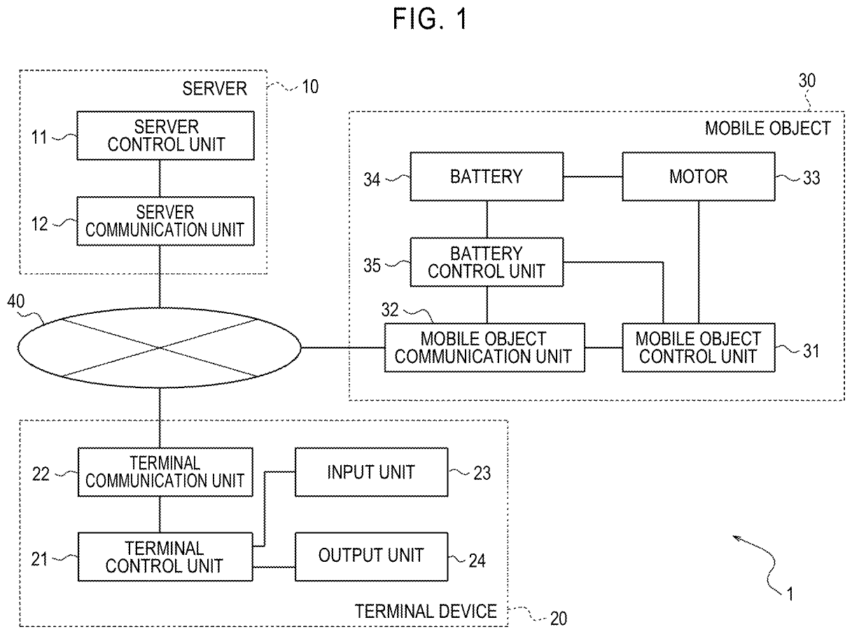

As illustrated in FIG. 1, a mobile object management system 1 according to an embodiment includes a server 10, a terminal device 20, and a mobile object 30. The server 10, the terminal device 20, and the mobile object 30 are connected to a network 40 and can communicate with each other. The number of servers 10, the number of terminal devices 20, and the number of mobile objects 30 are not limited to one and may be two or more.

A service for renting a mobile object 30 to a user is provided by the mobile object management system 1. The service for renting a mobile object 30 to a user is also referred to as a rental service. The server 10 processes information on a mobile object 30 which is rented to a user. The terminal device 20 receives a request for rental of a mobile object 30 from the user.

An example of a configuration of the mobile object management system 1 which is used to provide a rental service will be described below. Server 10

The server 10 includes a server control unit 11 and a server communication unit 12.

The server control unit 11 controls constituent units of the server 10. The server control unit 11 is also simply referred to as a control unit. The server control unit 11 may include one or more processors. In this embodiment, a “processor” is a general-purpose processor, a dedicated processor specialized for specific processes, or the like, but the processor is not limited thereto. The server control unit 11 may include one or more dedicated circuits. Examples of a dedicated circuit include a field-programmable gate array (FPGA) and an application-specific integrated circuit (ASIC). The server control unit 11 may include a dedicated circuit instead of a processor or may include a dedicated circuit in addition to a processor.

The server 10 may further include a storage unit. Examples of the storage unit include a semiconductor memory, a magnetic memory, and an optical memory, but the storage unit is not limited thereto. For example, the storage unit may serve as a main storage device, an auxiliary storage device, or a cache storage device. The storage unit may include an electromagnetic storage medium such as a magnetic disk. The storage unit stores arbitrary information which is used for the operation of the server 10. For example, the storage unit may store a system program or an application program. The storage unit may be included in the server control unit 11.

The server communication unit 12 includes a communication module that is configured to communicate with the terminal device 20 or the mobile object 30 via the network 40. The server communication unit 12 is also simply referred to as a communication unit.

The server 10 may include one server device or a plurality of server devices that can communicate with each other. The server 10 is also referred to as a mobile object management device.

### Terminal Device 20

The terminal device 20 includes a terminal control unit 21, a terminal communication unit 22, an input unit 23, and an output unit 24. The terminal device 20 may include, for example, a terminal device such as a smartphone. The terminal device 20 may include a personal computer (PC) such as a laptop PC or a tablet PC. The terminal device 20 is not limited thereto and may include various types of devices.

The terminal control unit 21 controls the constituent units of the terminal device 20. The terminal control unit 21 is also simply referred to as a control unit. The terminal control unit 21 may include one or more processors. The terminal control unit 21 executes a program for realizing functions of the terminal device 20. The terminal control unit 21 may have the same or similar configuration as the server control unit 11. The terminal control unit 21 may include a storage unit.

The terminal communication unit 22 may include a communication module that is configured to communicate with the server 10 via the network 40. The communication module may include a communication module corresponding to a mobile communication standard such as 4th Generation (4G) or 5th Generation (5G), but the communication module is not limited thereto. The terminal communication unit 22 is also simply referred to as a communication unit.

The input unit 23 includes an input device that receives an input from a user.

The input device may include, for example, a touch panel or a touch sensor or a pointing device such as a mouse. The input device may include physical keys. The input device may include a sound input device such as a microphone.

The output unit 24 outputs information such that a user can recognize the information. The output unit 24 may include, for example, a display device that outputs visual information such as images, text, or figures. The display device may include, for example, a liquid crystal display (LCD), an organic electroluminescence (EL) display, an inorganic EL display, or a plasma display panel (PDP). The display device is not limited to these displays and may include various other types of displays. The display device may include a light emitting device such as a light emission diode (LED). The display device may include various other types of devices.

The output unit 24 may include, for example, a sound output device such as a speaker that outputs auditory information such as speech. The output unit 24 is not limited thereto and may include various other devices.

### Mobile Object 30

The mobile object 30 includes a battery 34 and a motor 33. The mobile object 30 travels by driving the motor 33 with electric power with which the battery 34 is charged. That is, the mobile object 30 that is rented to a user in this embodiment is a motor-driven mobile object. The mobile object 30 may include a vehicle with four wheels such as an automobile. The mobile object 30 may include a vehicle with two wheels such as a bicycle or a motor bike or may include a vehicle with three wheels. The mobile object 30 may include a personal mobility such as a Ha:mo (registered trademark). The mobile object 30 is not limited thereto and may include various vehicles which can be ridden by a user.

The mobile object 30 further includes a mobile object control unit 31, a mobile object communication unit 32, and a battery control unit 35. The mobile object control unit 31, the mobile object communication unit 32, and the battery control unit 35 are communicatively connected to each other via an onboard network such as a controller area network (CAN) or a dedicated communication line.

The mobile object control unit 31 controls the constituent units of the mobile object 30. The mobile object control unit 31 is also simply referred to as a control unit. The mobile object control unit 31 may include one or more processors. The mobile object control unit 31 may include one or more dedicated circuits instead of a processor or may include one or more dedicated circuits in addition to a processor. The mobile object control unit 31 may further include a storage unit.

The mobile object communication unit 32 may include a communication module that is configured to communicate with the server 10 via the network 40. The communication module may include a communication module corresponding to a mobile communication standard such as 4G or 5G, but the communication module is not limited thereto. The mobile object communication unit 32 may include, for example, an onboard communication device. The mobile object communication unit 32 is also simply referred to as a communication unit.

The battery control unit 35 acquires a state of charge (SOC) from the battery 34 and controls charging and discharging of the battery 34 based on the state of charge. The battery control unit 35 outputs the state of charge of the battery 34 from the mobile object communication unit 32 to the server 10 or the terminal device 20.

The mobile object 30 further includes a position information acquiring unit which is not essential. The position information acquiring unit is communicatively connected to the mobile object control unit 31 or the mobile object communication unit 32 via an onboard network such as a CAN or a dedicated communication line. The position information acquiring unit acquires position information of the mobile object 30. The position information acquiring unit may include a receiver corresponding to a satellite positioning system. The receiver corresponding to a satellite positioning system may include, for example, a Global Positioning System (GPS) receiver. The mobile object 30 may output the position information of the mobile object 30 acquired by the position information acquiring unit from the mobile object communication unit 32 to the server 10. Operation example of rental service

An operation example of a rental service will be described below.

It is assumed that the rental service is provided by at least one operation entity. The operation entity provides a rental service by renting a mobile object 30 under management thereof to a user based on predetermined conditions. The operation entity manages stations in which mobile objects 30 which are rented to users are stored. Each station may be configured to store a mobile object 30. Each station may include a device that manages information on a mobile object 30.

A user can request rental of a mobile object 30 from the operation entity. A user can request rental of a mobile object 30 by designating at least one of a point at which the mobile object 30 is rented and a point at which the mobile object 30 is returned. A user can designate a station managed by the operation entity as the point at which the mobile object 30 is rented or the point at which the mobile object 30 is returned.

The server control unit 11 of the server 10 acquires information on a mobile object 30. The information on the mobile object 30 includes the state of charge of the battery 34. The information on the mobile object 30 may include information indicating whether the mobile object 30 is stored in a station or rented to a user. The information on the mobile object 30 may include position information of the mobile object 30. It may be determined whether the mobile object 30 is stored in a station or rented to a user based on the position information of the mobile object 30. The server control unit 11 may acquire the information on the mobile object 30 from the mobile object 30 or from a device that is installed in the station. The information on the mobile object 30 is also referred to as mobile object information.

The server control unit 11 may acquire information on a station from a device that is installed in the station. The information on the station may include information on a mobile object 30 that is stored in the station. The information on the station may include information on a space in which a mobile object 30 can be stored in the station. The information on the station is also referred to as station information.

The server control unit 11 acquires information on a request for rental of a mobile object 30 from a user from the terminal device 20. The information on the request for rental of a mobile object 30 is also referred to as request information. The request information includes information on a point or an area in which rental of a mobile object 30 is desired by a user or information on a point or an area in which return of a mobile object 30 is desired by a user.

The server control unit 11 determines whether to accept a user's request based on the request information. When it is determined that the user's request is accepted, the server control unit 11 determines a station in which a mobile object 30 is rented to the user and a station in which the mobile object 30 is returned by the user. The station in which a mobile object 30 is rented to a user is also referred to as a rental station. The station in which a mobile object 30 is returned by a user is also referred to as a return station. From the viewpoint of encouraging a user to move a mobile object 30 using the mobile object management system 1, the rental station and the return station can be referred to as a departure station and an arrival station.

The server control unit 11 assigns a mobile object 30 which is rented to a user out of mobile objects 30 stored in the rental station. When a user's request is accepted, the server control unit 11 outputs information on the mobile object 30 assigned to the user to the terminal device 20 and notifies the user of the information. The server control unit 11 may output information on the rental station and the return station to the terminal device 20 and notify the user of the information.

The server 10 may be operated by the operation entity that provides the rental service.

The terminal control unit 21 of the terminal device 20 acquires mobile object information or station information from the server 10 via the terminal communication unit 22. The terminal control unit 21 notifies a user of the mobile object information or the station information by causing the output unit 24 to output the mobile object information or the station information. The terminal control unit 21 receives an input of a request for rental of a mobile object 30 from the user via the input unit 23. The terminal control unit 21 may execute an application for receiving an input of a request for rental of a mobile object 30 from a user.

The terminal control unit 21 may receive an input of information indicating a point or an area in which a mobile object 30 is rented and a point or an area in which a mobile object 30 is returned as the request for rental of the mobile object 30. The terminal control unit 21 may receive an input of information for designating a mobile object 30 as the request for rental of the mobile object 30. The terminal control unit 21 may allow a user to input a request via the input unit 23 by causing the output unit 24 to output mobile object information or station information such that the user can see the information.

The terminal control unit 21 receives an input for selecting a station from the user via the input unit 23. The terminal control unit 21 may receive an input of information for determining which of a rental station and a return station the user is to select first via the input unit 23. The terminal control unit 21 can confirm selection of one of the rental station and the return station by receiving an input for selecting the station from the user after the user has determined which of the rental station and the return station to select first. The terminal control unit 21 can confirm selection of both of the rental station and the return station by determining which of the rental station and the return station has been selected after the input for selecting one station has been received. The station which is selected first by the user out of the rental station and the return station is also referred to as a first selection station. The station which is then selected by the user out of the rental station and the return station is also referred to as a second selection station.

The terminal control unit 21 generates request information based on the input of the request from the user and outputs the generated request information from the terminal communication unit 22 to the server 10. The terminal control unit 21 acquires information for identifying a mobile object 30 which is rented to the user from the server 10 via the terminal communication unit 22 and notifies the user of the acquired information.

It is assumed that the terminal device 20 is carried by a user. The terminal device 20 may be installed at a predetermined position such that at least one user can use it.

In this embodiment, the operation entity that provides the rental service needs to manage a state of charge of the battery 34 of a mobile object 30. For example, a mobile object 30 may be included as an object which is rented to a user when the state of charge of the battery 34 is equal to or greater than a rentable threshold value, and may be excluded as an object which is rented to a user when the state of charge of the battery 34 is less than the rentable threshold value. The rentable threshold value may be set to a minimum state of charge required for a mobile object 30 to move between stations with a user therein. The rentable threshold value is set to, for example, a value such as 30%.

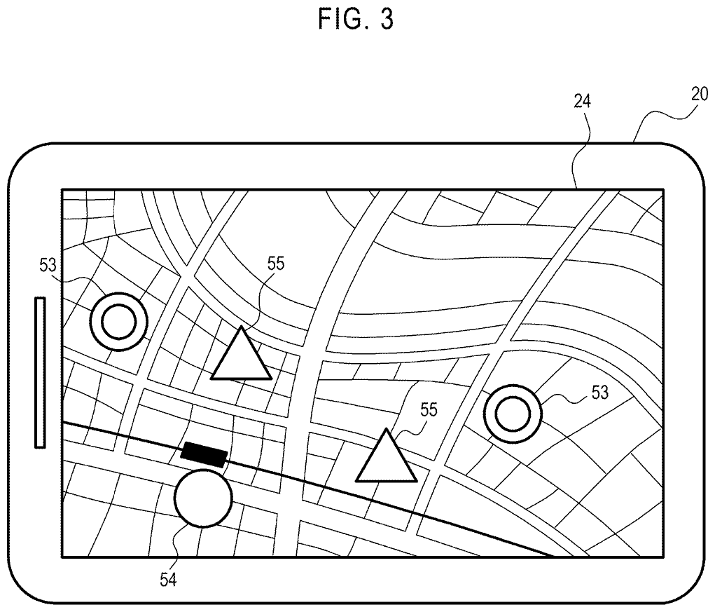

The stations include a charging station 53 (see FIG. 3) that is configured to charge the battery 34 of a mobile object 30 stored therein by including a facility that charges the battery 34. The stations also include a non-charging station 55 (see FIG. 3) that is not configured to charge the battery 34. The operation entity moves a mobile object 30 such that the mobile object 30 is stored in the charging station 53 to charge the battery 34 when the state of charge of the battery 34 of the mobile object 30 is less than an SOC threshold value. The SOC threshold value is set to a value which is greater than the rentable threshold value. The SOC threshold value may be set to a value with which the corresponding mobile object 30 can move to the charging station 53 before the state of charge of the battery 34 becomes less than the rentable threshold value. The SOC threshold value may be set to, for example, a value such as 50%. The SOC threshold value may be set to a value with which the corresponding mobile object 30 can move to the charging station 53 before the state of charge of the battery 34 becomes less than a drivable threshold value with which the battery 34 can drive the mobile object 30. The operation entity may move the mobile object 30 to the charging station 53 by itself. The operation entity may move the mobile object 30 to the charging station 53 by causing a user to return the mobile object 30 to the charging station 53 when the mobile object 30 has been rented to the user.

The mobile object management system 1 according to this embodiment moves a mobile object 30 to the charging station 53 by causing a user to return the mobile object 30 to the charging station 53. Accordingly, it is possible to decrease a burden with which the operation entity manages charging of the mobile object 30. The mobile object management system 1 encourages a user to return a mobile object 30 to the charging station 53 by providing an incentive to the user for movement of the mobile object 30. A configuration in which the mobile object management system 1 provides an incentive to a user for movement of a mobile object 30 will be described below.

The server control unit 11 of the server 10 acquires mobile object information or station information and outputs the acquired information to the terminal device 20. The server control unit 11 acquires request information on rental of a mobile object 30 to a user from the terminal device 20. The server control unit 11 determines an incentive which is provided to the user based on the state of charge of the battery 34 of the mobile object 30 which is rented to the user and a return station which is selected by the user. Specifically, when the state of charge of the battery 34 of the mobile object 30 which is rented to the user is less than the SOC threshold value and the return station is the charging station 53, the server control unit 11 provides an incentive to the user. The server control unit 11 may provide an incentive to the user after ascertaining that the user has returned the mobile object 30 to the charging station 53.

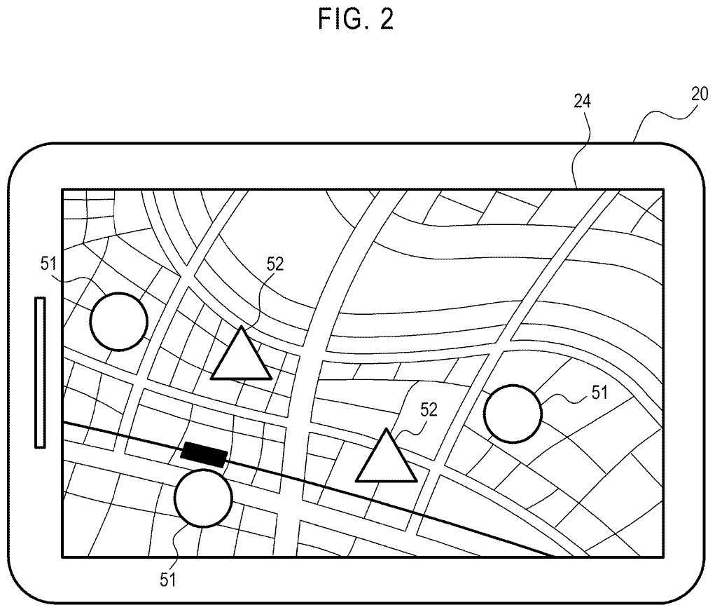

The terminal control unit 21 of the terminal device 20 acquires the mobile object information or the station information and causes the output unit 24 to display the acquired information. For example, it is assumed that the output unit 24 is configured as a display of the terminal device 20 as illustrated in FIGS. 2 and 3. The output unit 24 may display stations to overlap a map displayed on the display.

When the user selects a rental station, the output unit 24 may display a station in which a mobile object 30 in which the state of charge of the battery 34 is less than the SOC threshold value is stored such that the user can easily find it. The mobile object 30 in which the state of charge of the battery 34 is less than the SOC threshold value is also referred to as a low-SOC mobile object. Specifically, the output unit 24 may display a station in which a low-SOC mobile object is stored and a station in which a low-SOC mobile object is not stored such that the user can distinguish them from each other. The station in which a low-SOC mobile object is stored is also referred to as a low-SOC station 51. The station in which a low-SOC mobile object is not stored is also referred to as a non-low-SOC station 52.

For example, as illustrated in FIG. 2, the output unit 24 may distinguishably display the low-SOC station 51 and the non-low-SOC station 52. When the user selects a rental station, the output unit 24 may display the stations such that the user can distinguish the low-SOC station 51 and the non-low-SOC station 52 from each other. In the example illustrated in FIG. 2, the low-SOC station 51 is represented by a circle (O). The non-low-SOC station 52 is represented by a triangle (A). In this way, the stations may be distinguished from each other by displaying the stations in different figures. The stations may be distinguishably displayed by characters or symbols indicating the stations. The stations may be distinguishably displayed by colors of figures, characters, or symbols indicating the stations. The stations may be distinguishably displayed in various forms without being limited to these examples.

When the user selects a return station, the output unit 24 may display the charging station 53 such that the user can easily find it. Specifically, the output unit 24 may distinguishably display the charging station 53 and the non-charging station 55.

For example, as illustrated in FIG. 3, the output unit 24 may distinguishably display the charging station 53 and the non-charging station 55 when the user selects a return station. The output unit 24 may distinguishably display a station which has been already selected as a rental station by the user as a departure station 54. In the example illustrated in FIG. 3, the charging station 53 is represented by a double circle (O). The non-charging station 55 is represented by a triangle (A). The departure station 54 is represented by a circle (O). In this way, the stations may be distinguished from each other by displaying the stations in different figures. The stations may be distinguishably displayed by characters or symbols indicating the stations. The stations may be distinguishably displayed by colors of figures, characters, or symbols indicating the stations. The stations may be distinguishably displayed in various forms without being limited to these examples.

The terminal control unit 21 may receive an input for selecting a rental station and a return station from the user via the input unit 23. In the examples illustrated in FIGS. 2 and 3, it is assumed that the input unit 23 is configured as a touch panel of the terminal device 20. The input unit 23 receives an input for selecting a station by allowing the user to touch the station displayed on a map.

The terminal control unit 21 may receive an input for selecting a rental station and receive an input for selecting a mobile object 30 which is rented to the user from the mobile object 30 stored in the rental station.

The terminal control unit 21 outputs information on the rental station and the return station selected by the user from the terminal communication unit 22 to the server 10. The terminal control unit 21 may additionally output information on the mobile object 30 selected by the user to the server 10. The server 10 determines whether to accept or reject a request of rental of the mobile object 30 based on the information on the rental station and the return station selected by the user or the information on the mobile object 30 selected by the user. When a result of selection of the mobile object 30 is not acquired from the terminal device 20, the server 10 may appropriately select a mobile object 30 which is rented to the user out of mobile objects 30 stored in the rental station. The terminal control unit 21 acquires information on determination of whether to accept or reject a request from the server 10 via the terminal communication unit 22 and notifies the user of the information via the output unit 24. When the request for rental of the mobile object 30 is accepted, the server 10 determines whether to provide an incentive to the user. When an incentive is provided to the user, the server 10 determines details of an incentive which is provided to the user and a means for providing the incentive. The server 10 outputs information on the incentive to the terminal device 20.

The server 10 and the terminal device 20 may notify the user of the information on the incentive before the user selects the mobile object 30 and the return station. Specifically, the server control unit 11 may calculate an incentive which is provided to the user when the user moves a low-SOC mobile object to the charging station 53, and output information on the mobile object 30 and information on the incentive to the terminal devices 20 in correlation. Accordingly, it is possible to generate a motive for selecting a mobile object 30 and a return station such that the user can acquire an incentive.

As a result, the mobile object management system 1 can cause a user to return a mobile object 30 in which the state of charge of the battery 34 is less than the SOC threshold value to the charging station 53.

As described above, the mobile object management system 1 according to this embodiment can charge a low-SOC mobile object by providing an incentive to a user who has returned the low-SOC mobile object to the charging station 53. Accordingly, it is possible to decrease a burden of charging management of a mobile object 30.

The operation of the server 10 can be described in different ways as follows. The server control unit 11 calculates an incentive which is provided to a user when the user moves a low-SOC mobile object 30 to the charging station 53 based on the state of charge of the battery 34. The server control unit 11 outputs information on the mobile object 30 and information on the incentive to the terminal device 20 in correlation.

The operation of the terminal device 20 can be described in different ways as follows. The output unit 24 outputs information on a mobile object 30 and information on a station. The input unit 23 receives an input for selecting a mobile object 30 which is rented to a user and an input for selecting a return station in which the user returns the mobile object 30. The terminal control unit 21 outputs information for designating the mobile object 30 and the return station to the server 10. The terminal control unit 21 acquires information on an incentive which is determined based on the state of charge of the battery 34 from the server 10. The output unit 24 outputs the information on the mobile object 30 and the information on the incentive in correlation. Incentive

When a user owns a terminal device 20, the server control unit 11 may provide an incentive by outputting information on the incentive to the terminal device 20.

When a user does not own a terminal device 20, the server control unit 11 may provide an incentive to the user without using the terminal device 20 by allowing the user to input information required for providing an incentive as request information.

The server control unit 11 may provide points which can be used as a rental fee of a mobile object 30 in the rental service as an incentive. The server control unit 11 may provide electronic money as an incentive or may provide points which can be exchanged with valuables or a charged service as the incentive.

The server control unit 11 may increase an incentive which is provided to a user as the state of charge of the battery 34 of a low-SOC mobile object which is moved by the user decreases. Accordingly, the user is more likely to select a low-SOC mobile object.

Display of incentive at the time of selection of station

When a user first selects a rental station, the terminal control unit 21 may cause the output unit 24 to display that there is a likelihood that an incentive will be able to be provided when the user selects a low-SOC station 51. Accordingly, it is possible to enhance a motive for the user to select the low-SOC station 51. When the user has selected a low-SOC station 51, the terminal control unit 21 may cause the output unit 24 to display that there is a likelihood that an incentive will be able to be provided when the user selects a low-SOC mobile object. Accordingly, it is possible to enhance a motive for the user to select the low-SOC mobile object. The terminal control unit 21 may cause the output unit 24 to display that an incentive will be able to be provided when the user selects the charging station 53 as a return station. Accordingly, it is possible to enhance a motive for the user to return a low-SOC mobile object to the charging station 53. As a result, it is possible to enhance the likelihood that the user will be able to move a low-SOC mobile object to the charging station 53.

When a user first selects a return station, the terminal control unit 21 may cause the output unit 24 to display that there is a likelihood that an incentive will be able to be provided when the user selects a charging station 53. Accordingly, it is possible to enhance a motive for the user to select the charging station 53 as the return station. When the user has selected the charging station 53 as the return station, the terminal control unit 21 may cause the output unit 24 to display that there is a likelihood that an incentive will be able to be provided when the user selects a low-SOC station 51 as a rental station. Accordingly, it is possible to enhance a motive for the user to select the low-SOC station 51 as the rental station. The terminal control unit 21 may cause the output unit 24 to display that an incentive will be able to be provided when the user selects a low-SOC mobile object.

Accordingly, it is possible to enhance a motive for the user to return a low-SOC mobile object to the charging station 53. As a result, it is possible to enhance the likelihood that the user will be able to move a low-SOC mobile object to the charging station 53.

As described above, the mobile object management system 1 according to this embodiment provides an incentive when a user returns a low-SOC mobile object to a charging station 53. Accordingly, it is possible to encourage a user to move a low-SOC mobile object to a charging station 53. As a result, it is possible to decrease a burden of charging management of a mobile object 30.

### Example of Mobile Object Management Method

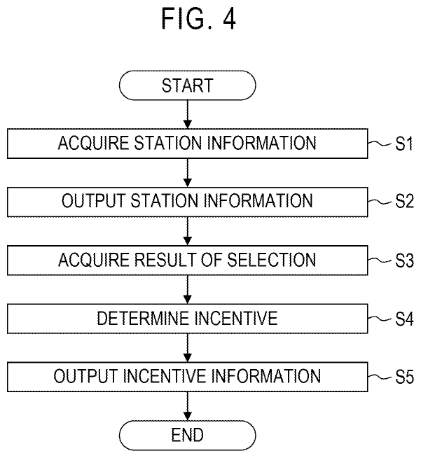

The server control unit 11 may perform a mobile object management method including the routine of the flowchart illustrated in FIG. 4. The mobile object management method may be realized as an information processing program which is executed by a processor constituting the server control unit 11.

The server control unit 11 acquires station information (Step S1).

The server control unit 11 outputs the station information to a terminal device 20 (Step S2).

The server control unit 11 acquires a result of selection of a station from the terminal device 20 (Step S3). The server control unit 11 may acquire the result of selection of a mobile object 30 which is rented to a user.

The server control unit 11 determines an incentive which is provided to the user based on the results of selection of the mobile object 30 which is rented to the user and the return station (Step S4).

The server control unit 11 outputs information on the incentive to the terminal device 20 (Step S5). The server control unit 11 ends execution of the routine of the flowchart illustrated in FIG. 4 after performing the process of Step S5.

### Example of Terminal Control Method

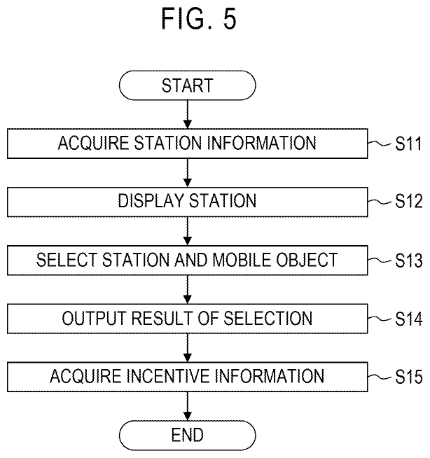

The terminal control unit 21 may perform a terminal control method including the routine of the flowchart illustrated in FIG. 5. The terminal control method may be realized as a terminal control program which is executed by a processor constituting the terminal control unit 21.

The terminal control unit 21 acquires station information from the server 10 (Step S11).

The terminal control unit 21 causes the output unit 24 to display the station information (Step S12).

The terminal control unit 21 receives an input for selecting a station and an input for selecting a mobile object 30 which is rented to the user via the input unit 23 (Step S13).

The terminal control unit 21 outputs the received result of selection to the server 10 (Step S14).

The terminal control unit 21 acquires information on an incentive from the server 10 (Step S15). The terminal control unit 21 causes the output unit 24 to display the information on an incentive. The terminal control unit 21 ends execution of the routine of the flowchart illustrated in FIG. 5 after performing the process of Step S15.

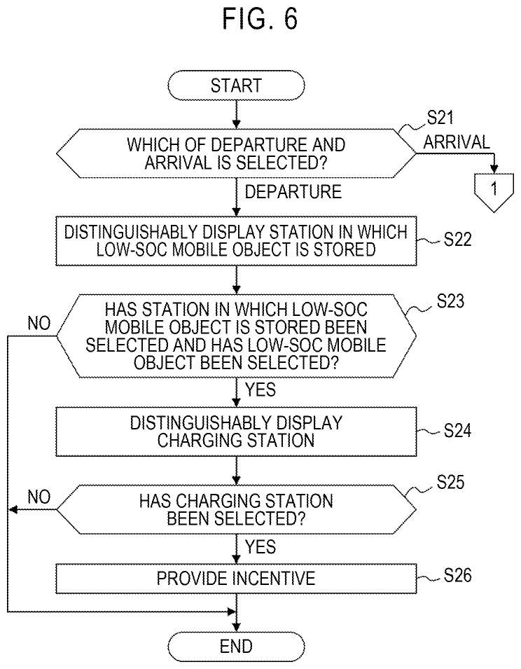

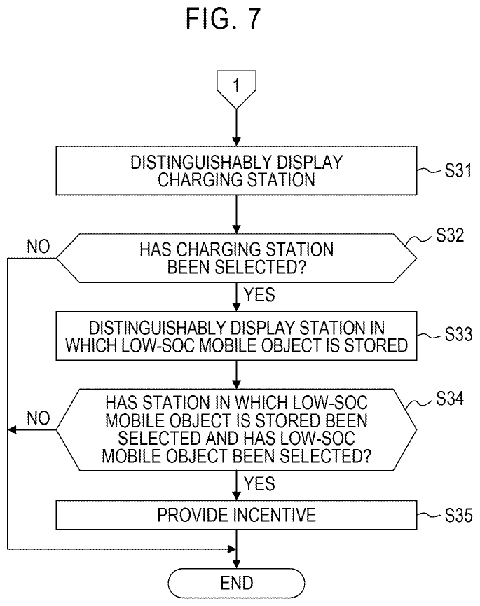

The terminal control unit 21 may perform a terminal control method including the routines of the flowcharts illustrated in FIGS. 6 and 7.

The terminal control unit 21 determines which of a departure station (a rental station) and an arrival station (a return station) a user first selects (Step S21). The terminal control unit 21 may receive an input for designating which the user first selects via the input unit 23. When the user first selects the departure station (Step S21: departure), the terminal control unit 21 performs the process of Step S22 in FIG. 6. When the user first selects the arrival station (Step S21: arrival), the terminal control unit 21 performs the process of Step S31 in FIG. 7.

When the user first selects the departure station (Step S21: departure), the terminal control unit 21 causes the output unit 24 to distinguishably display a station (a low-SOC station 51) in which a low-SOC mobile object is stored and a non-low-SOC station 52 (Step S22).

The terminal control unit 21 determines whether the user has selected a station (a low-SOC station 51) in which a low-SOC mobile object is stored as a departure station and has selected a low-SOC mobile object as the mobile object 30 which is rented to the user (Step S23). When the user has not selected a low-SOC station 51 or has not selected a low-SOC mobile object (Step S23: NO), the terminal control unit 21 ends execution of the routine of the flowchart illustrated in FIG. 6.

When the user has selected a low-SOC station 51 and has selected a low-SOC mobile object (Step S23: YES), the terminal control unit 21 causes the output unit 24 to distinguishably display a charging station 53 and a non-charging station 55 as display for allowing the user to select an arrival station (Step S24).

The terminal control unit 21 determines whether the user has selected the charging station 53 as the arrival station (Step S25). When the user has not selected the charging station 53 (Step S25: NO), the terminal control unit 21 ends execution of the routine of the flowchart illustrated in FIG. 6.

When the user has selected the charging station 53 (Step S25: YES), the terminal control unit 21 acquires information on an incentive from the server 10 and provides the incentive to the user (Step S26). The terminal control unit 21 ends execution of the routine of the flowchart illustrated in FIG. 6 after performing the process of Step S26.

When the user has first selected the arrival station (Step S21: arrival), the terminal control unit 21 causes the output unit 24 to distinguishably display a charging station 53 and a non-charging station 55 (Step S31 in FIG. 7).

The terminal control unit 21 determines whether the user has selected the charging station 53 as the arrival station (Step S32). When the user has not selected the charging station 53 (Step S32: NO), the terminal control unit 21 ends execution of the routine of the flowchart illustrated in FIG. 7.

When the user has selected the charging station 53 (Step S32: YES), the terminal control unit 21 causes the output unit 24 to distinguishably display a station (a low-SOC station 51) in which a low-SOC mobile object is stored and a non-low-SOC station 52 as display for allowing the user to select a departure station (Step S33).

The terminal control unit 21 determines whether the user has selected a station (a low-SOC station 51) in which a low-SOC mobile object is stored as the departure station and has selected a low-SOC mobile object as the mobile object 30 which is rented to the user (Step S34). When the user has not selected the low-SOC station 51 or has not selected a low-SOC mobile object (Step S34: NO), the terminal control unit 21 ends execution of the routine of the flowchart illustrated in FIG. 7.

When the user has selected a low-SOC station 51 and has selected a low-SOC mobile object (Step S34: YES), the terminal control unit 21 acquires information on an incentive from the server 10 and provides the incentive to the user (Step S35). The terminal control unit 21 ends execution of the routine of the flowchart illustrated in FIG. 7 after performing the process of Step S35.

As described above, with the mobile object management method and the terminal control method according to this embodiment, it is possible to provide an incentive to a user who has returned a low-SOC mobile object to a charging station 53. Accordingly, it is possible to encourage a user to move a low-SOC mobile object to a charging station 53. As a result, it is possible to decrease a burden of charging management of a mobile object 30.

### Other Embodiments

The server control unit 11 of the server 10 may provide an incentive to a user when the user has moved a mobile object 30 to a charging station 53 and has returned the mobile object 30 to a storage space configured to charge the mobile object 30. The terminal control unit 21 of the terminal device 20 may cause the output unit 24 to distinguishably display a charging station 53 in which a storage space configured to charge a mobile object 30 is empty and a charging station 53 in which a storage space configured to charge a mobile object 30 is not empty out of the charging stations 53. Accordingly, it is possible to easily charge a mobile object 30. As a result, it is possible to decrease a burden of charging management of a battery 34 of a mobile object 30.

While the present disclosure has been described above in conjunction with all the drawings and the embodiments, it should be noted by those skilled in the art that various modifications and corrections can be easily made based on the present disclosure. Accordingly, it should be noted that such modifications and corrections are included in the scope of the present disclosure. For example, the functions included in the constituent units or the steps can be rearranged unless technical conflictions arise, and a plurality of constituent units or steps may be combined into one constituent unit or step, or one constituent unit or step may be divided.

What is claimed is:

1. A mobile object management device comprising a control unit configured to calculate an incentive which is provided to a user when the user moves a motor-driven mobile object that is driven by a battery to a charging station configured to charge the motor-driven mobile object based on a state of charge of the battery,
wherein the control unit is configured to output information on the motor-driven mobile object and information on the incentive to a terminal device in correlation.

2. The mobile object management device according to claim 1, wherein the control unit is configured to determine that the incentive is provided to the user when the state of charge of the battery is less than an SOC threshold value.

3. The mobile object management device according to claim 1, wherein the control unit is configured to increase the incentive as the state of charge of the battery decreases.

4. The mobile object management device according to claim 1, wherein the control unit is configured to cause the terminal device to distinguishably display the charging station and a non-charging station which is not configured to charge the motor-driven mobile object.

5. The mobile object management device according to claim 4, wherein the control unit is configured to cause the terminal device to display the charging station and the non-charging station in different figures.

6. The mobile object management device according to claim 1, wherein the control unit is configured to cause the terminal device to distinguishably display a station in which a motor-driven mobile object of which the state of charge of the battery is less than an SOC threshold value is stored and a station in which a motor-driven mobile object of which the state of charge of the battery is less than the SOC threshold value is not stored.

7. The mobile object management device according to claim 1, wherein the control unit is configured to cause the terminal device to distinguishably display a charging station in which a storage space which is configured to charge the motor-driven mobile object is empty and a charging station in which a storage space which is configured to charge the motor-driven mobile object is not empty.

8. A mobile object management system comprising:
the mobile object management device according to claim 1; and
the terminal device.

9. A mobile object management method comprising:
calculating an incentive which is provided to a user when the user moves a motor-driven mobile object that is driven by a battery to a charging station configured to charge the motor-driven mobile object based on a state of charge of the battery; and
outputting information on the motor-driven mobile object and information on the incentive to a terminal device in correlation.

10. The mobile object management method according to claim 9, further comprising determining that the incentive is provided to the user when the state of charge of the battery is less than an SOC threshold value.

11. The mobile object management method according to claim 9, further comprising increasing the incentive as the state of charge of the battery decreases.

12. The mobile object management method according to claim 9, further comprising causing the terminal device to distinguishably display the charging station and a non-charging station which is not configured to charge the motor-driven mobile object.

13. The mobile object management method according to claim 12, further comprising causing the terminal device to display the charging station and the non-charging station in different figures.

14. The mobile object management method according to claim 9, further comprising causing the terminal device to distinguishably display a station in which a motor-driven mobile object of which the state of charge of the battery is less than an SOC threshold value is stored and a station in which a motor-driven mobile object of which the state of charge of the battery is less than the SOC threshold value is not stored.

15. The mobile object management method according to claim 9, further comprising causing the terminal device to distinguishably display a charging station in which a storage space in which the motor-driven mobile object is to be stored is empty and a charging station in which a storage space in which the motor-driven mobile object is to be stored is not empty.

16. A terminal device comprising:
an output unit configured to output information on a motor-driven mobile object that is driven by a battery and information on a station of the motor-driven mobile object;
an input unit configured to receive an input for selecting the motor-driven mobile object which is rented to a user and an input for selecting a return station to which the motor-driven mobile object is returned by the user; and
a control unit configured to output information for selecting the motor-driven mobile object and the return station to a mobile object management device,
wherein the control unit is configured to acquire information on an incentive which is determined based on a state of charge of the battery and which is provided to the user from the mobile object management device and to cause the output unit to output the information on the motor-driven mobile object and the information on the incentive in correlation.

17. The terminal device according to claim 16, wherein the output unit is configured to distinguishably display a charging station which is configured to charge the motor-driven mobile object and a non-charging station which is not configured to charge the motor-driven mobile object.

18. The terminal device according to claim 17, wherein the output unit is configured to display the charging station and the non-charging station in different figures.

19. The terminal device according to claim 16, wherein the output unit is configured to distinguishably display a station in which a motor-driven mobile object of which the state of charge of the battery is less than an SOC threshold value is stored and a station in which a motor-driven mobile object of which the state of charge of the battery is less than the SOC threshold value is not stored.

20. The terminal device according to claim 16, wherein the output unit is configured to distinguishably display a charging station in which a storage space which is configured to charge the motor-driven mobile object is empty and a charging station in which a storage space which is configured to charge the motor-driven mobile object is not empty.
